(19) United States
(12) Patent Application Publication
(10) Pub. No.: US 2020/0357843 A1
(43) Pub. Date: Nov. 12, 2020

(54) FOLDABLE DISPLAY PANEL

(71) Applicant: Shenzhen China Star Optoelectronics Semiconductor Display Technology Co., Ltd., Shenzhen, Guangdong (CN)

(72) Inventor: Baixiang HAN, Shenzhen, Guangdong (CN)

(21) Appl. No.: 16/621,240

(22) PCT Filed: Oct. 31, 2019
(86) PCT No.: PCT/CN2019/114550

§ 371 Date: Dec. 11, 2019

(30) Foreign Application Priority Data
May 8, 2019 (CN) 201910378864.X

(51) Int. Cl. H01L 27/15; H01L 33/40; H01L 33/42

(52) U.S. Cl. CPC H01L 27/156; H01L 33/42; H01L 33/405

(57) ABSTRACT

The present invention provides a foldable display panel, the foldable display panel includes a first display region, a second display region, and a folding region. The first display region includes a plurality of first pixel units. The second display region includes a plurality of second pixel units corresponding to the plurality of first pixel units. The second display region covers the first display region along the folding region when the folding region is deformed, and each of the plurality of second pixel units is located above corresponding each of the plurality of first pixel units.

### FIELD OF INVENTION

The present invention is related to the field of electronic display, and specifically to a foldable display panel.

### BACKGROUND OF INVENTION

With continuous development of display technology, users have higher requirements for resolution and service life of display panels. However, as resolution increases, limited by process capabilities, an aperture ratio of display panels inevitably decreases, and the service life shortens consequently.

### SUMMARY OF INVENTION

Referring to FIG. 1, FIG. 1 schematically shows one of pixels of a display panel in the prior art. Because it only allows one color of light to pass through at the same time, an aperture ratio of display panels in the prior art is only about 33%, which needs to be improved.

The present invention provides a foldable display panel for increasing the aperture ratio of display panels in the prior art.

In order to solve the problem above, the foldable display panel provided by the present invention includes:

a first display region, the first display region including a plurality of first pixel units, and each of the plurality of first pixel units including a first sub-pixel and a third sub-pixel;

a second display region, the second display region being symmetric with the first display region, the second display region including a plurality of second pixel units corresponding to the plurality of first pixel units, and each of the plurality of second pixel units including a second sub-pixel; and

a folding region, the folding region located on a symmetry axis of the first display region and the second display region, and the folding region connecting the first display region and the second display region;

wherein the second display region covers the first display region along the folding region when the folding region is deformed, and each of the plurality of second pixel units is located above corresponding each of the plurality of first pixel units; and

a control signal of the first display region and a control signal of the second display region are the same, and received display information of the plurality of first pixel units and received display information of the plurality of second pixel units corresponding thereto are the same.

According to one of aspects of the present invention, a shape and an area of each of the plurality of first pixel units and a shape and an area of each of the plurality of second pixel units are the same.

According to one of aspects of the present invention, an area of the first sub-pixel is equal to an area of the third sub-pixel.

According to one of aspects of the present invention, the first sub-pixel is a red pixel, the second sub-pixel is a blue pixel, and the third sub-pixel is a green pixel.

According to one of aspects of the present invention, the first display region is a top-emitting display panel, and the second display region is a double-sided light-emitting display panel.

According to one of aspects of the present invention, an anode of the first display region is a reflective electrode, and a cathode of the first display region is a transparent electrode; and an anode of the second display region is a transparent electrode, and a cathode of the second display region is a transparent electrode.

According to one of aspects of the present invention, the foldable display panel further includes a non-display region, the non-display region is located on a side of the first display region and the second display region, and the non-display region is parallel to the folding region.

According to one of aspects of the present invention, the foldable display panel further includes a non-display region, the non-display region is located on a side of the first display region and the second display region, and the non-display region is perpendicular to the folding region.

According to one of aspects of the present invention, the foldable display panel further includes a plurality of support columns located between the first display region and the second display region; and

a material of the plurality of support columns is a white material or a transparent material, and a surface of the plurality of support columns has a diffuse reflection structure.

In order to solve the problem above, the foldable display panel provided by the present invention includes:

a first display region, the first display region including a plurality of first pixel units, and each of the plurality of first pixel units including a first sub-pixel and a third sub-pixel;

a second display region, the second display region being symmetric with the first display region, the second display region including a plurality of second pixel units corresponding to the plurality of first pixel units, and each of the plurality of second pixel units including a second sub-pixel;

and

a folding region, the folding region located on a symmetry axis of the first display region and the second display region, and the folding region connecting the first display region and the second display region;

wherein the second display region covers the first display region along the folding region when the folding region is deformed, and each of the plurality of second pixel units is located above corresponding each of the plurality of first pixel units.

According to one of aspects of the present invention, a shape and an area of each of the plurality of first pixel units and a shape and an area of each of the plurality of second pixel units are the same.

According to one of aspects of the present invention, an area of the first sub-pixel is equal to an area of the third sub-pixel.

According to one of aspects of the present invention, the first sub-pixel is a red pixel, the second sub-pixel is a blue pixel, and the third sub-pixel is a green pixel.

According to one of aspects of the present invention, the first display region is a top-emitting display panel, and the second display region is a double-sided light-emitting display panel.

According to one of aspects of the present invention, an anode of the first display region is a reflective electrode, and a cathode of the first display region is a transparent electrode; and an anode of the second display region is a transparent electrode, and a cathode of the second display region is a transparent electrode.

According to one of aspects of the present invention, the foldable display panel further includes a non-display region, the non-display region is located on a side of the first display region and the second display region, and the non-display region is parallel to the folding region.

According to one of aspects of the present invention, the foldable display panel further includes a non-display region, the non-display region is located on a side of the first display region and the second display region, and the non-display region is perpendicular to the folding region.

According to one of aspects of the present invention, a control signal of the first display region and a control signal of the second display region are the same, and received display information of the plurality of first pixel units and received display information of the plurality of second pixel units corresponding thereto are the same.

According to one of aspects of the present invention, the foldable display panel further includes a plurality of support columns located between the first display region and the second display region.

According to one of aspects of the present invention, a material of the plurality of support columns is a white material or a transparent material, and a surface of the plurality of support columns has a diffuse reflection structure.

A foldable display panel provided by the present invention includes a first display region and a second display region disposed correspondingly. The first display region includes a plurality of first pixel units, and the second display region includes a plurality of second pixel units corresponding to the plurality of first pixel units. Each of the plurality of first pixel units includes a first sub-pixel and a third sub-pixel, and each of the plurality of second pixel units includes a second sub-pixel. After folding, each of the plurality of second pixel units is located above corresponding each of the plurality of first pixel units. With this arrangement, when the first sub-pixel or the third sub-pixel emits light, an aperture ratio of pixel units of the foldable display panel approaches 50%. When the second sub-pixel emits light, the aperture ratio of the pixel units of the foldable display panel approaches 100%. Therefore, the present invention greatly increases an aperture ratio of display panels, and optimizes a display effect of the display panels.

### DESCRIPTION OF DRAWINGS

FIG. 1 is a structural diagram of a display panel in the prior art.

FIG. 2 is a structural diagram of a foldable display panel in an expanded state according to an embodiment of the present invention.

FIG. 3 is a structural diagram of the foldable display panel in FIG. 2 in a folded state.

FIG. 4 is a structural diagram of a foldable display panel in an expanded state according to another embodiment of the present invention.

FIG. 5 is a structural diagram of the foldable display panel in FIG. 4 in a folded state.

### DETAILED DESCRIPTION OF PREFERRED EMBODIMENTS

Examples are described below with reference to the appended drawings, and the drawings illustrate particular embodiments in which the present invention may be practiced. Directional terms mentioned in the present invention, such as upper, lower, front, rear, left, right, in, out, side, etc., only refer to directions in the accompanying drawings. Thus, the adoption of directional terms is used to describe and understand the present invention, but not to limit the present invention. In the drawings, units of similar structures are using the same numeral to represent.

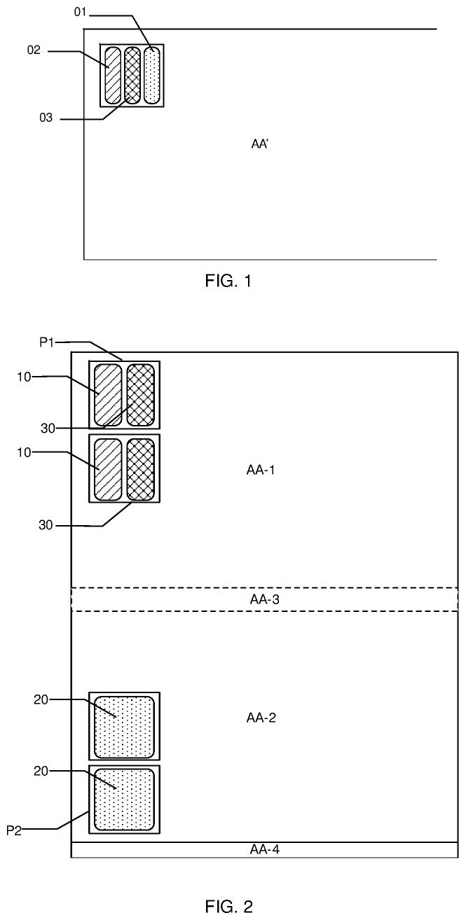

First, a brief description of the prior art, referring to FIG. 1, a display panel in the prior art includes a display region AA′, and the display region AA′ includes a plurality of pixel units. FIG. 1 schematically shows one of the plurality of pixel units. Each of the plurality of pixel units includes a first sub-pixel 01, a second sub-pixel 02, and a third sub-pixel 03. The first sub-pixel 01, the second sub-pixel 02, and the third sub-pixel 03 respectively emits red light, blue light, and green light. Each of the plurality of pixel units only emits one color of light at the same time when displaying, so an aperture ratio of display panels in the prior art is only about 33%, which needs to be improved.

Accordingly, the present invention provides a foldable display panel for increasing the aperture ratio of display panels in the prior art.

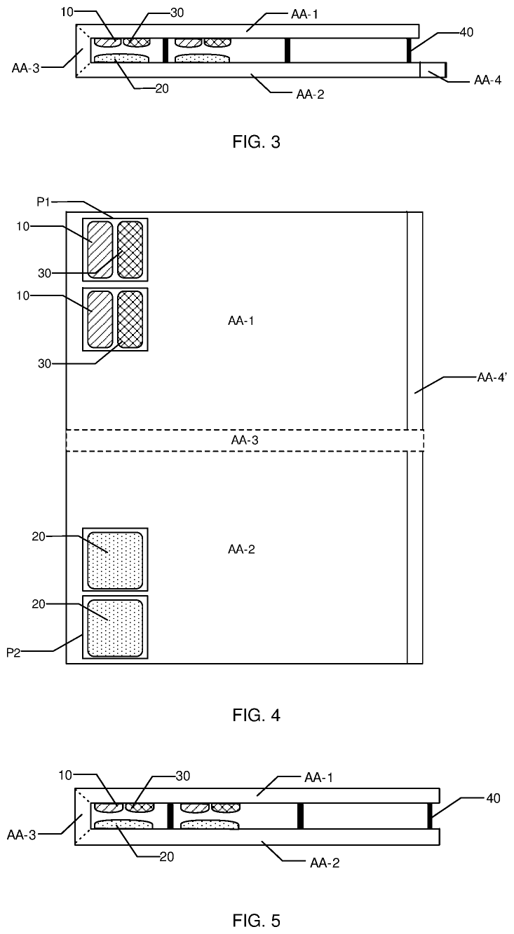

Referring to FIGS. 2 and 3, FIG. 2 is a structural diagram of a foldable display panel in an expanded state according to an embodiment of the present invention, and FIG. 3 is a structural diagram of the foldable display panel in FIG. 2 in a folded state.

The foldable display panel in the present invention includes a first display region AA-1, a second display region AA-2, and a folding region AA-3. Referring to FIG. 2, the first display region AA-1 includes a plurality of first pixel units P1, and each of the plurality of first pixel units P1 includes a first sub-pixel 10 and a third sub-pixel 30. The second display region AA-2 is symmetric with the first display region AA-1, the second display region AA-2 includes a plurality of second pixel units P2 corresponding to the plurality of first pixel units P1, and each of the plurality of second pixel P2 units comprising a second sub-pixel 20. The folding region AA-3 located on a symmetry axis of the first display region AA-1 and the second display region AA-2, and the folding region AA-3 connects the first display region AA-1 and the second display region AA-2.

Referring to FIG. 3, in this embodiment, the second display region AA-2 covers the first display region AA-1 along the folding region AA-3 when the folding region AA-3 is deformed, each of the plurality of second pixel units P2 is located above corresponding each of the plurality of first pixel units P1, and the plurality of first pixel units P1 and the plurality of second pixel units P2 are laminated to form pixel units of the foldable display panel.

In this embodiment, a shape and an area of each of the plurality of first pixel units and a shape and an area of each of the plurality of second pixel units are the same, so the plurality of first pixel units P1 and the plurality of second pixel units P2 can be laminated to form the pixel units of the foldable display panel after the first display region AA-1 overlaps the second display region AA-2. In this embodiment, the plurality of first pixel units P1 and the plurality of second pixel units P2 are rectangular, but are not limited to any other shape.

In this embodiment, the first sub-pixel 10 is a red pixel, the second sub-pixel 20 is a blue pixel, and the third sub-pixel 30 is a green pixel. An area of the first sub-pixel 10 is equal to an area of the third sub-pixel 30. Due to a shorter wavelength of blue light, power consumption of the blue pixel is greater, thin-film transistor and light-emitting diode of the blue pixel have greater loss, and the blue pixel ages more easily compared with the red pixel and the green pixel. In the prior art, since aging speed of blue pixels is faster, lifespan of the blue pixels determines lifespan of a display panel. The foldable display panel of the present invention uses the blue pixel as the second sub-pixel 20 and occupies each of the plurality of second pixel units P2, and it greatly reduces the power consumption of the blue pixel due to an aperture ratio of the blue light being close to 100%. Accordingly, the foldable display panel of the present invention significantly slows down aging of the blue pixel, and extends service life of the foldable display panel.

In the present embodiment, the first display region AA-1 is a top-emitting display panel, and the second display region AA-2 is a double-sided light-emitting display panel. The second display region AA-2 is a top-emitting display panel after being laminated to form the foldable display panel. An anode of the first display region AA-1 is a reflective electrode, and a cathode of the first display region AA-1 is a transparent electrode. An anode of the second display region AA-2 is a transparent electrode, and a cathode of the second display region AA-2 is a transparent electrode. The reflective electrode can be a conductive metal electrode such as silver, copper, gold, etc., having good electrical conductivity and reflectivity. The transparent electrode can be a transparent conductive material such as indium tin oxide.

As shown in FIGS. 2 and 3, in this embodiment, the foldable display panel further includes a non-display region AA-4, the non-display region AA-4 is located on a side of the first display region AA-1 and the second display region AA-2, and the non-display region AA-4 is parallel to the folding region AA-3. Film-coated chips and metal traces are disposed on the non-display region AA-4 for controlling display of the first display region AA-1 and the second display region AA-2.

In this embodiment, the folding region AA-3 is a bendable flexible film or a hinge structure controlling a shape the folding region AA-3 to realize expansion and folding of the foldable display panel. Film-coated chips and flexible printed circuits realize an electrical connection between the first display region AA-1 and the second display region AA-2. A control signal of the first display region AA-1 and a control signal of the second display region AA-2 are the same, and specifically, received display information of the plurality of first pixel units P1 and received display information of the plurality of second pixel units P2 corresponding thereto are the same.

As shown in FIGS. 4 and 5, FIG. 4 is a structural diagram of a foldable display panel in an expanded state according to another embodiment of the present invention, and FIG. 5 is a structural diagram of the foldable display panel in FIG. 4 in a folded state.

In another embodiment of the present invention, referring to FIG. 4, a foldable display panel includes a non-display region AA-4, the non-display region AA-4 is located on a side of a first display region AA-1 and a second display region AA-2, and the non-display region AA-4 is perpendicular to a folding region AA-3. Film-coated chips and metal traces are disposed on the non-display region AA-4 for controlling display of the first display region AA-1 and the second display region AA-2. A control signal of the first display region AA-1 and a control signal of the second display region AA-2 are the same, and specifically, received display information of a plurality of first pixel units P1 and received display information of a plurality of second pixel units P2 corresponding thereto are the same.

In this embodiment, the non-display region AA-4 directly electrically connects the first display region AA-1 and the second display region AA-2. In this embodiment, it can realize an electrical connection between the first display region AA-1 and the second display region AA-2, without needing to dispose film-coated chips or flexible printed circuits on the folding region AA-3. Accordingly, compared with the previous embodiment, manufacturing difficulty of the folding region AA-3 is greatly reduced, and manufacturing cost is reduced as well.

In embodiments of the present invention, the foldable display panel further includes a plurality of support columns 40 located between the first display region AA-1 and the second display region AA-2. The plurality of support columns 40 having a same height can support the second display region AA-2, disperse pressure from the second display region AA-2 to the first display region AA-1, and prevent the first display region AA-1 from generating cracks by uneven force. Also, the plurality of support columns 40 can ensure that a distance between the first display region AA-1 and the second display region AA-2 keeps constant, and prevent pixel units from offsetting causing by changing the distance between the first display region AA-1 and the second display region AA-2. Preferably, in order to prevent the plurality of support columns 40 from forming spots or shadows on the foldable display panel, a material of the plurality of support columns 40 is a white material or a transparent material, and a surface of the plurality of support columns 40 has a diffuse reflection structure.

A foldable display panel provided by the present invention includes a first display region and a second display region disposed correspondingly. The first display region includes a plurality of first pixel units, and the second display region includes a plurality of second pixel units corresponding to the plurality of first pixel units. Each of the plurality of first pixel units includes a first sub-pixel and a third sub-pixel, and each of the plurality of second pixel units includes a second sub-pixel. After folding, each of the plurality of second pixel units is located above corresponding each of the plurality of first pixel units. With this arrangement, when the first sub-pixel or the third sub-pixel emits light, an aperture ratio of pixel units of the foldable display panel approaches 50%. When the second sub-pixel emits light, the aperture ratio of the pixel units of the foldable display panel approaches 100%. Therefore, the present invention greatly increases an aperture ratio of display panels, and optimizes a display effect of the display panels.

Although the present invention has been disclosed above by the preferred embodiments, the preferred embodiments are not intended to limit the invention. One of ordinary skill in the art, without departing from the spirit and scope of the present invention, can make various modifications and variations of the present invention. Therefore, the scope of the claims to define the scope of equivalents.

What is claimed is:

1. A foldable display panel, comprising:
a first display region, the first display region comprising a plurality of first pixel units, and each of the plurality of first pixel units comprising a first sub-pixel and a third sub-pixel;
a second display region, the second display region being symmetric with the first display region, the second display region comprising a plurality of second pixel units corresponding to the plurality of first pixel units, and each of the plurality of second pixel units comprising a second sub-pixel; and
a folding region, the folding region located on a symmetry axis of the first display region and the second display region, and the folding region connecting the first display region and the second display region;
wherein the second display region covers the first display region along the folding region when the folding region is deformed, and each of the plurality of second pixel units is located above corresponding each of the plurality of first pixel units; and
a control signal of the first display region and a control signal of the second display region are the same, and received display information of the plurality of first pixel units and received display information of the plurality of second pixel units corresponding thereto are the same.

2. The foldable display panel as claimed in claim 1, wherein a shape and an area of each of the plurality of first pixel units and a shape and an area of each of the plurality of second pixel units are the same.

3. The foldable display panel as claimed in claim 2, wherein an area of the first sub-pixel is equal to an area of the third sub-pixel.

4. The foldable display panel as claimed in claim 3, wherein the first sub-pixel is a red pixel, the second sub-pixel is a blue pixel, and the third sub-pixel is a green pixel.

5. The foldable display panel as claimed in claim 1, wherein the first display region is a top-emitting display panel, and the second display region is a double-sided light-emitting display panel.

6. The foldable display panel as claimed in claim 5, wherein an anode of the first display region is a reflective electrode, and a cathode of the first display region is a transparent electrode; and
an anode of the second display region is a transparent electrode, and a cathode of the second display region is a transparent electrode.

7. The foldable display panel as claimed in claim 1, wherein the foldable display panel further comprises a non-display region, the non-display region is located on a side of the first display region and the second display region, and the non-display region is parallel to the folding region.

8. The foldable display panel as claimed in claim 1, wherein the foldable display panel further comprises a non-display region, the non-display region is located on a side of the first display region and the second display region, and the non-display region is perpendicular to the folding region.

9. The foldable display panel as claimed in claim 1, wherein the foldable display panel further comprises a plurality of support columns located between the first display region and the second display region; and
a material of the plurality of support columns is a white material or a transparent material, and a surface of the plurality of support columns has a diffuse reflection structure.

10. A foldable display panel, comprising:
a first display region, the first display region comprising a plurality of first pixel units, and each of the plurality of first pixel units comprising a first sub-pixel and a third sub-pixel;
a second display region, the second display region being symmetric with the first display region, the second display region comprising a plurality of second pixel units corresponding to the plurality of first pixel units, and each of the plurality of second pixel units comprising a second sub-pixel; and
a folding region, the folding region located on a symmetry axis of the first display region and the second display region, and the folding region connecting the first display region and the second display region;
wherein the second display region covers the first display region along the folding region when the folding region is deformed, and each of the plurality of second pixel units is located above corresponding each of the plurality of first pixel units.

11. The foldable display panel as claimed in claim 10, wherein a shape and an area of each of the plurality of first pixel units and a shape and an area of each of the plurality of second pixel units are the same.

12. The foldable display panel as claimed in claim 11, wherein an area of the first sub-pixel is equal to an area of the third sub-pixel.

13. The foldable display panel as claimed in claim 12, wherein the first sub-pixel is a red pixel, the second sub-pixel is a blue pixel, and the third sub-pixel is a green pixel.

14. The foldable display panel as claimed in claim 10, wherein the first display region is a top-emitting display panel, and the second display region is a double-sided light-emitting display panel.

15. The foldable display panel as claimed in claim 14, wherein an anode of the first display region is a reflective electrode, and a cathode of the first display region is a transparent electrode; and
an anode of the second display region is a transparent electrode, and a cathode of the second display region is a transparent electrode.

16. The foldable display panel as claimed in claim 10, wherein the foldable display panel further comprises a non-display region, the non-display region is located on a side of the first display region and the second display region, and the non-display region is parallel to the folding region.

17. The foldable display panel as claimed in claim 10, wherein the foldable display panel further comprises a non-display region, the non-display region is located on a side of the first display region and the second display region, and the non-display region is perpendicular to the folding region.

18. The foldable display panel as claimed in claim 10, wherein a control signal of the first display region and a control signal of the second display region are the same, and received display information of the plurality of first pixel units and received display information of the plurality of second pixel units corresponding thereto are the same.

19. The foldable display panel as claimed in claim 10, wherein the foldable display panel further comprises a plurality of support columns located between the first display region and the second display region.

20. The foldable display panel as claimed in claim 10, wherein a material of the plurality of support columns is a white material or a transparent material, and a surface of the plurality of support columns has a diffuse reflection structure.
